(19) United States
(12) Patent Application Publication
(10) Pub. No.: US 2025/0172628 A1
(43) Pub. Date: May 29, 2025

(54) METHOD AND DEVICE FOR DETECTING A FAILURE OF A LITHIUM-ION BATTERY CELL

(71) Applicant: COMMISSARIAT A L'ENERGIE ATOMIQUE ET AUX ENERGIES ALTERNATIVES, Paris (FR)

(72) Inventors: Jonathan DESEURE, Grenoble Cedex 09 (FR); Lauriane BICHOT, Grenoble Cedex 09 (FR); Maxime MONTARU, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/959,808

(22) Filed: Nov. 26, 2024

(30) Foreign Application Priority Data
Nov. 29, 2023 (FR) 2313274

(51) Int. Cl. G01R 31/392; G01R 31/378; G01R 31/385

(52) U.S. Cl. CPC G01R 31/392; G01R 31/378; G01R 31/385

(57) ABSTRACT

A method for detecting a failure of a cell of a Lithium-Ion battery. The method includes, for at least one CV phase of a CC-CV charging cycle of the cell:
collecting several measurements forming a floating current signal,
deriving the floating current signal,
decomposing into empirical modes the derivative of the floating current,
determining an incidence value representative of the state-of-health of the cell, for the considered CV phase, based on the intrinsic components obtained by the decomposition,
assessing a failure criterion of the cell according to the incidence value.

### TECHNICAL FIELD

The present invention relates to the field of management of “Lithium-Ion” type batteries. More particularly, a method and a device are provided for detecting a failure of a Lithium-Ion battery cell in particular in order to prevent an accident (explosion, fire or other) over the service life of the battery.

### BACKGROUND

There are currently different methods for detecting failures of Lithium batteries.

Some methods are based on measurements of electromechanical properties of the battery (vibration, acoustic waves, etc.). These measurements could be used to identify precocious signs of a failure, such as cracks, delaminations and manufacturing defects.

Some methods are based on measurements of thermal properties of the battery, such as the temperature, the thermal conductivity and the thermal capacity. These measurements could be used to identify an abnormal heat-up of the battery.

One drawback of these methods lies in the fact that the failure is detected quite late. Hence, these methods do not always allow preventing an accident related to a failure of the battery in a satisfactory way.

Other methods are based on measurements of the electrochemical properties of the battery, such as the voltage, the current, the resistance or the capacity.

Among these electrochemical methods, a large number of them are based on voltage signals measured at the level of the battery. For example, mention may be made of the patent applications US 2017/146608 A1 and US 2022/0381849 A1. In turn, the patent application EP 3324197 A1 describes a method for determining the state-of-health of a battery cell according to a ratio between a charge variation and a current difference measured between two time points of a CV phase (constant-voltage charging phase) of a CC-CV cycle (a charging cycle including a constant-current charging phase followed by a constant-voltage charging phase). Nonetheless, the reliability of these methods for detecting a failure is not always fully satisfactory. In particular, these methods do not generally allow anticipating a failure of a battery cell early enough.

### SUMMARY

An objective of the present invention is to overcome all or part of the drawbacks of the prior art, in particular those set out hereinbefore.

To this end, and according to a first aspect, a method is provided by the present invention for detecting a failure of a cell of a Lithium-Ion battery. The method includes, for at least one “constant-voltage” phase (CV phase), of a “constant-current-constant-voltage” charging cycle (CC-CV charging cycle) of the cell:
collecting a plurality of current measurements performed at the level of the cell during said at least one CV phase, said plurality of measurements forming a “floating current” signal,
deriving the floating current signal to obtain a floating current derivative signal,
decomposing into empirical modes the floating current derivative signal in order to obtain therefrom a representation in the form of a sum of a residual signal and of one or more intrinsic component(s),
determining an incidence value representative of a state-of-health of the cell, for said at least one CV phase, based on the intrinsic components thus obtained,
assessing a detection criterion of a failure of the cell according to the incidence value of said at least one CV phase.

In some particular modes of implementation, the invention may further include one or more of the following features, considered separately or according to any technically-feasible combinations.

In particular modes of implementation, the determination of the incidence value, for said at least one CV phase, comprises:
calculating an energy for each intrinsic component,
calculating a total intrinsic energy equal to a sum of the energies of the intrinsic components,
determining the incidence value according to the total intrinsic energy thus calculated.

In particular modes of implementation, the determination of the incidence value, for said at least one CV phase, comprises:
calculating a spectral density for each intrinsic component,
calculating a total intrinsic spectral density equal to a sum of the spectral densities of the different intrinsic components,
determining the incidence value according to the total intrinsic spectral density thus calculated.

In particular modes of implementation, for each intrinsic component, the spectral density of the intrinsic component is calculated based on a Hilbert transform of the intrinsic component.

The proposed method clearly stands out from the conventional methods as it is based on the analysis of the derivative of the floating current during a CV phase of a CC-CV charging cycle. At first glance, nothing suggests that this signal contains relevant information for monitoring the state-of-health of the cell.

The empirical mode decomposition is particularly well suited to the analysis of this signal. This decomposition further has the advantage of being relatively fast and efficient in terms of computing capacity.

Monitoring the total intrinsic energy or the total intrinsic spectral density of the cell allows detecting a failure early and effectively.

In particular modes of implementation, the method further includes, for said at least one CV phase, estimating a statistical reliability of the CV phase, according to the intrinsic components of the floating current derivative signal. The CV phase is filtered if it is found to be unreliable.

In particular modes of implementation, the statistical reliability of the CV phase is estimated according to an entropy calculated for a sum of the intrinsic components of the floating current derivative signal.

In particular modes of implementation, the statistical reliability of the CV phase is estimated by comparing the total intrinsic energy with a predetermined energy threshold, or with the total intrinsic energies calculated for all or part of the previous CV phases.

This step of filtering the CV phases found to be statistically unreliable allows discarding the CV phases featuring aberrant incidence values.

In particular modes of implementation, the assessment of the detection criterion of a failure of the cell includes comparing the incidence value with a predetermined incidence threshold, for said at least one CV phase.

In particular modes of implementation, the assessment of the detection criterion of a failure of the cell includes comparing a slope of a linear interpolation performed for a set of several incidence values corresponding to several consecutive CV phases with a predetermined slope threshold.

In particular modes of implementation, the assessment of the detection criterion of a failure of the cell includes comparing the incidence value for said at least one CV phase with an incidence value of a previous CV phase.

These different criteria may be used, individually or in combination, to detect a failure of the cell.

In particular modes of implementation, when a failure is detected, the method further includes verifying whether the detected failure is related to the environment in which the cell has evolved.

In particular modes of implementation, the verification of whether the detected failure is related to the environment comprises comparing, for a given period including said at least one CV phase, incidence values determined for the cell during said period with incidence values determined for at least one other cell subjected to the same environment during said period.

In particular modes of implementation, the verification of whether the detected failure is related to the environment comprises comparing, for a given period including said at least one CV phase, environment measurements performed during said period with a predetermined threshold.

Indeed, it might be advantageous to know whether a detected failure is related to the environment in which the cell has evolved. If the failure is related to the environment, it is possible to take a corrective step at the level of the environment of the cell, and the failure will probably have a limited impact over time. A failure that is not related to the environment is probably more serious since it foreshadows a failure intrinsic to the cell, like for example a failure related to a manufacturing defect or to a precocious degradation of the cell. A failure intrinsic to the cell might require safeguarding the cell to avoid a risk of accident (swelling of the cell, risk of rupture of a case enclosing the cell, thermal runaway, fire or explosion risk, etc.).

According to a second aspect, a device is provided by the present invention for detecting a failure of a cell of a Lithium-Ion battery. The device includes:
a battery management system configured to supply current measurements performed at the level of the cell during a “constant-voltage” phase, or CV phase, of a “constant-current-constant-voltage” charging cycle, or CC-CV charging cycle, of the cell,
a computing unit connected to the battery management system, said computing unit being configured to implement a method according to any one of the previously-described modes of implementation.

### BRIEF DESCRIPTION OF THE DRAWINGS

The invention will be better understood upon reading the following description, given as a non-limiting example, and made with reference to FIGS. 1 to 15 which show:

FIG. 1 is a schematic representation of the main steps of an example of implementation of the method according to the invention for detecting a failure of a cell of a Lithium-Ion battery,

FIG. 2 is a schematic representation of a particular mode of implementation of the step of determining an incidence value,

FIG. 3 a schematic representation of another particular mode of implementation of the step of determining an incidence value,

FIG. 4 a graph representing the current flowing in a Lithium-Ion battery cell over four successive CC-CV charging cycles,

FIG. 5 a graph representing the floating current flowing in a Lithium-Ion battery cell over a CV phase of a CC-CV charging cycle of the cell,

FIG. 6 a graph representing the derivative of the floating current represented in FIG. 5,

FIG. 7 a graph representing a decomposition into empirical modes of the floating current derivative represented in FIG. 6,

FIG. 8 a schematic representation of a particular mode of implementation of the step of assessing a detection criterion of a failure of the cell,

FIG. 9 a first example of incidence values determined successively for seven CV phases,

FIG. 10 a second example of incidence values determined successively for seven CV phases,

FIG. 11 a third example of incidence values determined successively for seven CV phases,

FIG. 12 a fourth example of incidence values determined successively for seven CV phases,

FIG. 13 a graph representing the evolution over time of the incidence value of a battery cell, as well as the evolution over tome, during the same period, of the temperature experienced by the cell,

FIG. 14 a graph representing another example of the evolution over time of the incidence value of a battery cell, as well as the evolution over time, during the same period, of the temperature experienced by the cell,

FIG. 15 a schematic representation of a device according to the invention allowing detecting a failure of a cell of a Lithium-Ion battery.

In these figures, identical references from one figure to another designate identical or similar elements. For clarity, the elements shown are not necessarily plotted to the same scale, unless stated otherwise.

### DETAILED DESCRIPTION

As indicated before, the present application provides a method and a device for detecting a failure of a cell of a Lithium-Ion battery.

A charging cycle of a Lithium-Ion battery cell conventionally includes two phases: a first phase of constant-current charging, or CC phase (CC stands for “Constant Current”) and a second phase of constant-voltage charging, or CV phase (CV stands for “Constant Voltage”). We then talk about a CC-CV charging cycle. In the present invention, we focus on the current that flows in the cell during the CV phase. In general, this current is called “floating current”.

Although the first charging phase (CC phase) is conventionally performed at constant current, more elaborate charging schemes could exist during this first phase, with an evolution of the current for example to maximize the charging speed while remaining in the charging domain compatible with the accumulator. The end of the first charging phase is then marked by reaching a voltage threshold that triggers toggling into the second phase of constant-voltage charging (CV phase). For simplicity, it will be considered that these particular cases of the first charging phase are also covered by the expression CC-CV “constant current-constant voltage” charging used in this application.

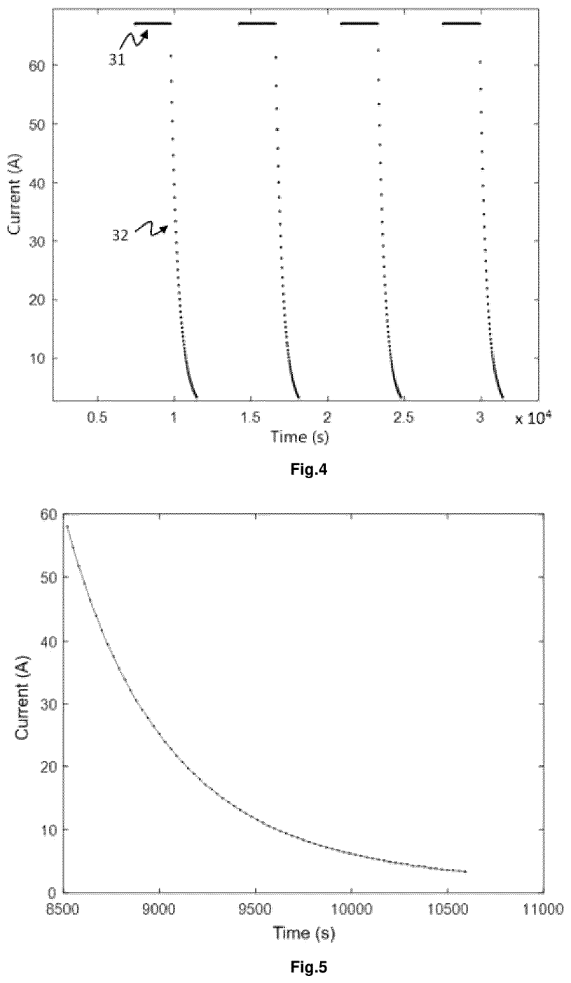

FIG. 4 is a graph representing four successive CC-CV charging cycles of a Lithium-Ion battery cell. The current that flows in the cell is represented in the ordinate axis (in amps) and the time is represented in the abscissa axis (in seconds). Each cycle includes a CC phase 31 and a CV phase 32. As illustrated in the graph of FIG. 4, the current that flows in the cell during the CC phase 31 is substantially constant, and it features an exponential decrease during the CV phase 32. FIG. 5 is a graph showing in a more detailed manner the CV phase 32 of a CC-CV charging cycle of the cell.

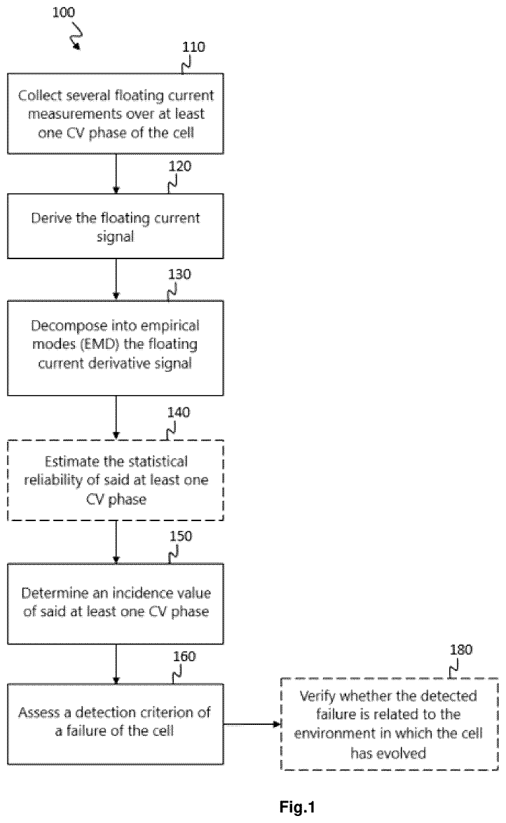

FIG. 1 schematically represents the main steps of an example of implementation of a method 100 according to the invention for detecting a failure of a cell of a Lithium-Ion battery.

As illustrated in FIG. 1, the method 100 includes the following steps, for at least one CV phase of a CC-CV charging cycles of the cell:
collecting 110 several floating current measurements during the CV phase,
deriving 120 the floating current thus obtained,
decomposing into empirical modes 130 (EMD, standing for “Empirical Mode Decomposition”) of the derivative of the floating current,
determining 150 an incidence value representative of a state-of-health of the cell based on the intrinsic components obtained by the EMD decomposition,
assessing 160 a detection criterion of a failure of the cell according to the incidence value thus determined.

These steps may be implemented for the CV phase of one or more CC-CV charging cycle(s) undergone by the cell over its service life. For example, they may be implemented at each new CV phase of the cell, in order to carry out a systematic monitoring of the state-of-health of the cell. Nonetheless, there is nothing preventing, in one variant, from implementing these steps only for a subset of all charging cycles of the cell, for example each time a given number of charging cycles has been completed, or at a predetermined time frequency. These steps may also be implemented sporadically over the service life of the cell.

For example, the floating current measurements during the CV phase are performed by a battery management system (BMS) connected to the cell. For example, the measurements are performed with an acquisition frequency comprised between one and sixty second(s), during an acquisition duration of ten to sixty minutes. Nonetheless, there is nothing preventing from making the measurements with a different acquisition frequency, and/or during a different acquisition duration. It is advantageous to use a number of measurements comprised between thirty and fifty per CV phase (using a larger number of measurements does not necessarily imply a significant improvement of the method, using a smaller number of measurements could however limit the performances of the method). All of the measurements collected during the collection step 110 form a “floating current” signal. The graph of FIG. 5 represents an example of a floating current signal obtained in the collection step 110.

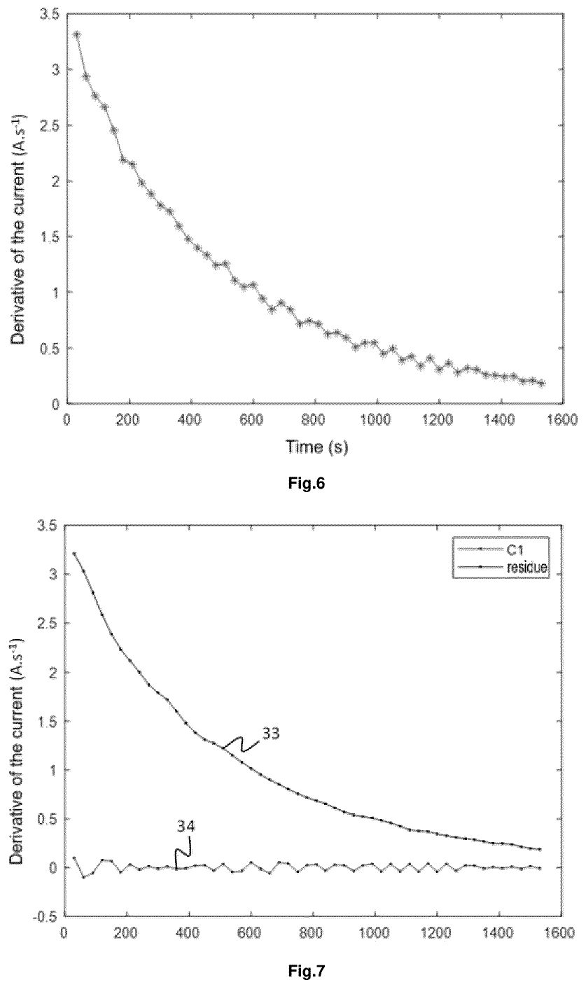

In the derivation step 120, the floating current signal obtained in step 110 is derived to obtain a floating current derivative signal. The graph of FIG. 6 represents an example of a floating current derivative signal obtained in the derivation step 120 (it consists of the floating current signal derivative represented in the graph of FIG. 5).

In step 130, the floating current derivative signal is decomposed according to an empirical mode decomposition. It should be noted that the floating current signal is generally too “smooth” and that it hardly enables an empirical mode decomposition, this is why we focus on its derivative, even though, at first glance, nothing would suggest that this floating current derivative signal would contain relevant information on the state-of-health of the cell.

The empirical mode decomposition consists in decomposing a signal in the form of a sum of functions, in a similar way as the Fourier series decomposition or the wavelet decomposition.

One of the particularities of the empirical mode decomposition is that the function base according to which the signal is decomposed is not known a priori, but it is built in an adaptive way according to the properties of the signal.

The empirical mode decomposition corresponds to the first portion of the Hilbert-Huang transform (HHT). The empirical mode decomposition consists in decomposing a signal in the form of a sum of a residual signal and of intrinsic mode functions (IMF). In the present application, these intrinsic mode functions are also called “intrinsic components”.

As indicated before, the intrinsic components are not defined analytically. They are rather determined in an adaptive way according to the properties of the signal.

An intrinsic component (IMF) resulting from an empirical mode decomposition (EMD) should meet the following requirements:
The number of extrema (i.e. the sum of the number of the local maxima and of the number of the local minima) and the number of zero crossings of the intrinsic component should be equal or differ at most by one;
at any point of the intrinsic component, the average value of the envelope defined by the local maxima and of the envelope defined by the local minima is zero.

A signal s(t) decomposed by EMD could then be written in the form:

$$s ( t ) = r ( t ) + {\sum }_{i = 1}^{N} {c}_{i} ( t )$$

In this expression, r(t) corresponds to the residual signal, N is the number of intrinsic components of the EMD decomposition, and cᵢ(t) is the intrinsic component with the index i. Each successive intrinsic component cᵢ contains frequency oscillations lower than those of the previous one. The residual signal corresponds to a general tendency of the signal s(t).

The empirical mode decomposition includes a series of sifting processes. The first sifting process directly takes on the signal s(t) as input. The sifting process corresponds to identifying all of the local extrema of the input signal, and to connecting the local maxima, respectively the local minima, via a cubic spline interpolation, in order to obtain an upper envelope, respectively a lower envelope. An average between the upper envelope and the lower envelope could then be calculated and subtracted from the input signal. If the obtained intermediate signal (subtraction of the input signal with the average of the upper and lower envelopes) is not an intrinsic component, the sifting process is reiterated on the intermediate signal (which therefore becomes the input signal of a new sifting process) until obtaining an intrinsic component. The sifting processes are repeated until obtaining the last intrinsic component, i.e. for example until the intermediate signal becomes monotone or it includes only one single local extremum. The remaining signal then corresponds to the residual signal r(t).

A stop criterion may be defined for the sifting process. For example, the stop criterion is met if the standard deviation between the results of two successive sifting processes is lower than or equal to a predetermined stop threshold. The stop threshold may typically be comprised between 0.2 and 0.3.

The document “The empirical mode decomposition and the Hilbert spectrum for non-linear and non-stationary time series analysis”, by Norden E. Huang et al., Proc. R. Soc. Lond. A (1998) 454, p. 903-995, describes in detail the empirical mode decomposition, in particular in its sections 4 and 5.

Empirical mode decomposition algorithms are available in programming libraries, for example in the MATLAB or Python language.

The graph of FIG. 7 represents an example of empirical mode decomposition of the floating current derivative signal represented in FIG. 6. In the considered example illustrated in FIG. 7, the empirical mode decomposition has resulted in one single intrinsic component 34 (c₁) and a residual signal 33. It should be noted that, in other examples, a larger number of intrinsic components could be obtained. Nonetheless, the number of intrinsic components generally remains less than five. It is advantageous to set the stop threshold at a relatively low level, in the range of 0.2, to extract as much information as possible from the floating current derivative signal. Using a lower stop threshold imposes particularly long calculation times.

The intrinsic components obtained in step 130 are then used in step 150 to determine an incidence value representative of the state-of-health of the cell for the considered CV phase.

Different methods may be considered to determine the incidence value associated with the considered CV phase.

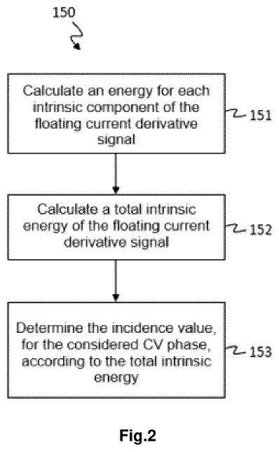

According to a first example, and as illustrated in FIG. 2, the determination 150 of the incidence value may include:
calculating 151 an energy for each intrinsic component,
calculating 152 a total intrinsic energy equal to the sum of the energies of the intrinsic components, and
determining 153 the incidence value according to the total intrinsic energy thus calculated.

For example, the energy Eᵢ of an intrinsic component cᵢ corresponds to the integral of the square of the amplitude of the intrinsic component cᵢ over the acquisition duration of the considered CV phase:

$${E}_{i} = \int {\vert {c}_{i} ( t ) \vert}^{2} dt$$

The total intrinsic energy E of the considered CV phase could then be written in the form:

$$E = {\sum }_{i = 1}^{N} {E}_{i}$$

It should be noted that there is nothing preventing, in one variant, from calculating the total intrinsic energy E by summing up the energies of only a subset of the intrinsic components obtained by the EMD decomposition (for example, by considering only a predefined maximum number of the first intrinsic components obtained by the EMD decomposition).

The incidence value of the considered CV phase may then correspond to the total intrinsic energy of the CV phase, or to an average value of the total intrinsic energy for all or part of the total intrinsic energies calculated for previous CV phases.

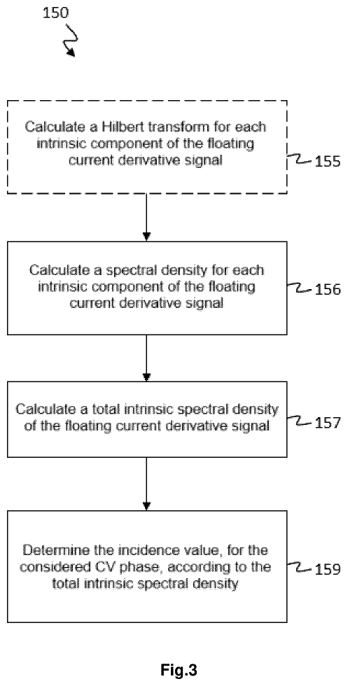

According to a second example, and as illustrated in FIG. 3, the determination 150 of the incidence value may include:
calculating 156 a spectral density for each intrinsic component,
calculating 157 a total intrinsic spectral density equal to the sum of the spectral densities of the intrinsic components (or possibly equal to the sum of the spectral densities of the intrinsic components of only one subset of the intrinsic components), and
determining 159 the incidence value according to the total intrinsic spectral density thus calculated.

For example, the incidence value of the considered CV phase may correspond to the surface area of the total intrinsic spectral density of the CV phase, or to an average value of the surface area of the total intrinsic spectral density for all or part of the total intrinsic energies calculated for previous CV phases. The incidence value could also correspond to a set of samples of the total intrinsic spectral density.

Nonetheless, there is nothing preventing from determining the incidence value of a CV phase by combining the total intrinsic energy and the total intrinsic spectral density. For example, the incidence value may correspond to a pair of values including the total intrinsic energy and the surface area (or a set of samples) of the total intrinsic spectral density of the considered CV phase.

In particular, the spectral densities of the different intrinsic components may be calculated by the Welch method. Nonetheless, there is nothing preventing from using other spectral density estimation methods, like for example the Bartlett or Blackman-Tukey methods.

Optionally, the spectral density of each intrinsic component may be calculated based on a Hilbert transform of the intrinsic component. For this purpose, and as illustrated in FIG. 3, the step of determining 150 the incidence value includes an additional step of calculating 155 a Hilbert transform of each intrinsic component of the floating current derivative signal, prior to the step of calculating 156 the spectral densities of the intrinsic components.

The Hilbert transform allows extending a real signal in the complex domain. The transformed signal then features zero amplitude responses at the zero frequencies. This allows avoiding artifacts during the exploitation of the information contained in the processed signal. Thus, the Hilbert transform allows optimizing the spectral density calculation.

Algorithms enabling these Hilbert transform and spectral density estimation calculations are available in programming libraries, for example in MATLAB or in Python.

As illustrated in FIG. 1, the method 100 according to the invention may also include an optional step of estimating 140 a statistical reliability of the considered CV phase, and a filtering of the CV phase if the latter is found to be unreliable.

This filtering of a CV phase found to be unreliable allows avoiding taking account of the aberrant values in the analysis of the state-of-health of the cell.

The statistical reliability of a CV phase is estimated according to the intrinsic components of the floating current derivative signal obtained for the CV phase.

According to a first example, the statistical reliability of the CV phase is estimated according to an entropy calculated for a sum of the intrinsic components of the floating current derivative signal (for example for the sum of all of the intrinsic components obtained by the EMD decomposition, or for the sum of a predefined maximum number of the first intrinsic components obtained by the EMD decomposition). Different entropy calculation methods may be considered, like for example a Shannon entropy calculation, or a Kolmogorov entropy calculation. For example, the CV phases for which the calculated entropy is too low (lower than a predetermined entropy threshold) are filtered. In particular, a Shannon entropy threshold comprised between 0.25 and 0.5 may be considered.

According to a second example, the statistical reliability of the CV phase is estimated by comparing the total intrinsic energy calculated for the CV phase with a predetermined energy threshold. For example, the CV phases that have an aberrant total intrinsic energy value (higher than the energy threshold) are filtered.

According to still another example, the statistical reliability of the CV phase is estimated by comparing the total intrinsic energy calculated for the CV phase with the total intrinsic energies calculated for all or part of the previous CV phase(s) (for example the total intrinsic energies may be compared with one another, or the total intrinsic energy of the current CV phase may be compared with an average value of total intrinsic energies of previous CV phases). For this purpose, different statistical tests may be considered (Pierce test, Pierson test, etc.).

Different criteria may be used, individually or in combination, to detect a failure of the cell based on the incidence value determined for one or more CV phase(s).

According to a first example, it is possible to consider comparing the incidence value with a predetermined incidence threshold, for one or more CV phase(s). If the incidence value (for example the total intrinsic energy, or the surface area of the total intrinsic spectral density) is higher than the incidence threshold, then an alert could be triggered. A failure may be detected when a given number of alerts is reached.

According to a second example, for each new considered CV phase, it is possible to consider performing a linear interpolation over the incidence values determined respectively for the new CV phase and for each of a given number of previous CV phases, and comparing the slope of the linear interpolation with a predetermined slope threshold. If the slope is higher than the slope threshold (for example if the slope is strictly positive), then an alert could be triggered. A failure may be detected when a given number of alerts is reached.

According to a third example, it is possible to consider comparing the incidence value of a CV phase with an incidence value of a previous CV phase. For example, it is possible to verify whether, for a set of several incidence values corresponding to several previous CV phases, the incidence value of the most recent CV phase is higher than or equal to the incidence value of the earliest CV phase.

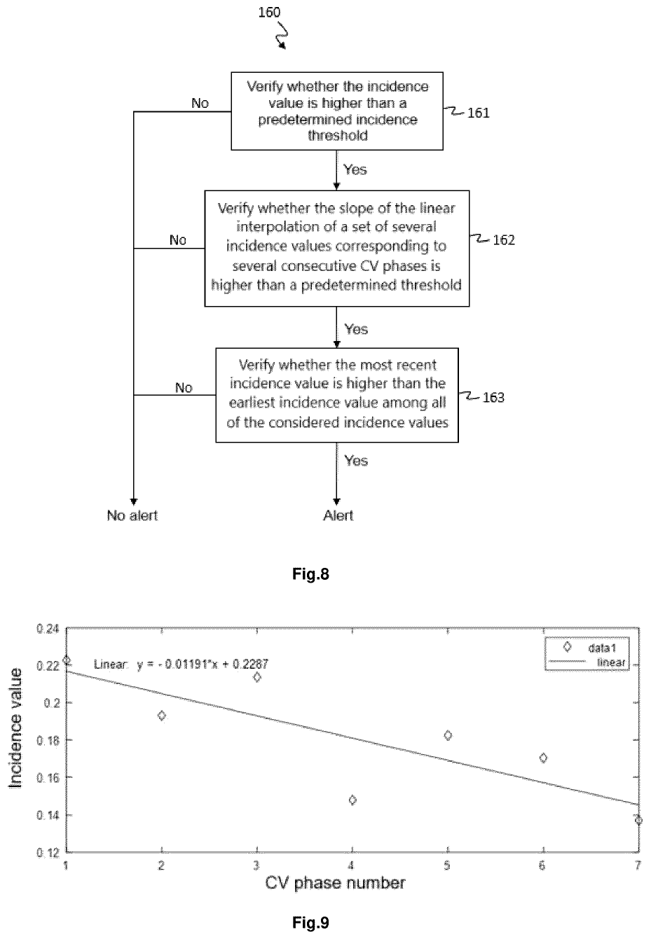

FIGS. 8 to 12, illustrate as a non-limiting example, how these different criteria could be combined to detect a failure of the cell. In the considered example, and as illustrated in FIG. 8, the step of assessing 160 the detection criterion of a failure of the cell includes in a first step verifying 161 whether the incidence value is higher than an incidence threshold. If so is the case, then, it is proceeded with a verification 162 of whether the slope of the linear interpolation of the incidence values determined for the considered last seven phases is strictly positive. If so is the case, then it is proceeded with a verification 163 of whether, amongst the considered last seven phases CV, the most recent incidence value is strictly higher than the earliest incidence value. If so is the case, then an alert is triggered. Insofar as at least one of the conditions verified in steps 161 to 163 is not met, no alert is triggered. When three alerts are triggered for three considered CV phases consecutively, then a failure is detected.

In the considered example illustrated in FIGS. 9 to 12, an incidence value for a CV phase corresponds to a rolling average value of the total intrinsic energies calculated for the considered last twenty CV phases (including the current CV phase). The incidence threshold is set at 0.15 A²s⁻¹.

It should be noted that many other variants would be possible. For example, it would be possible to consider that the incidence value of a CV phase corresponds to the total intrinsic energy calculated for said CV phase (without using a rolling average), and perform the linear interpolation over a larger number of intrinsic values (for example fifty). It would also be possible to consider using the surface area of the total intrinsic spectral density as an incidence value, instead of the total intrinsic energy. Also, other values could be considered for the incidence threshold, the slope threshold, the number of values to be considered for the linear interpolation, the number of values to be considered for the rolling average, the number of alerts to be triggered to trigger the detection of a failure, etc. These particular choices for the implementation of the step of assessing 160 the detection criterion of a failure of the cell are just but variants of the invention.

In the example illustrated in FIG. 9, the current incidence value (incidence value with the index seven) is lower than the incidence threshold, and the slope of the linear interpolation of the last seven incidence values is negative (in other words, the conditions of the verifications 161 and 162 are not met). Consequently, no alert is triggered. Although the previous incidence values with the index one, two, three, five and six were higher than the incidence threshold, no alert has neither been triggered because the slope of the linear interpolation of the last seven incidence value was also negative at these time points.

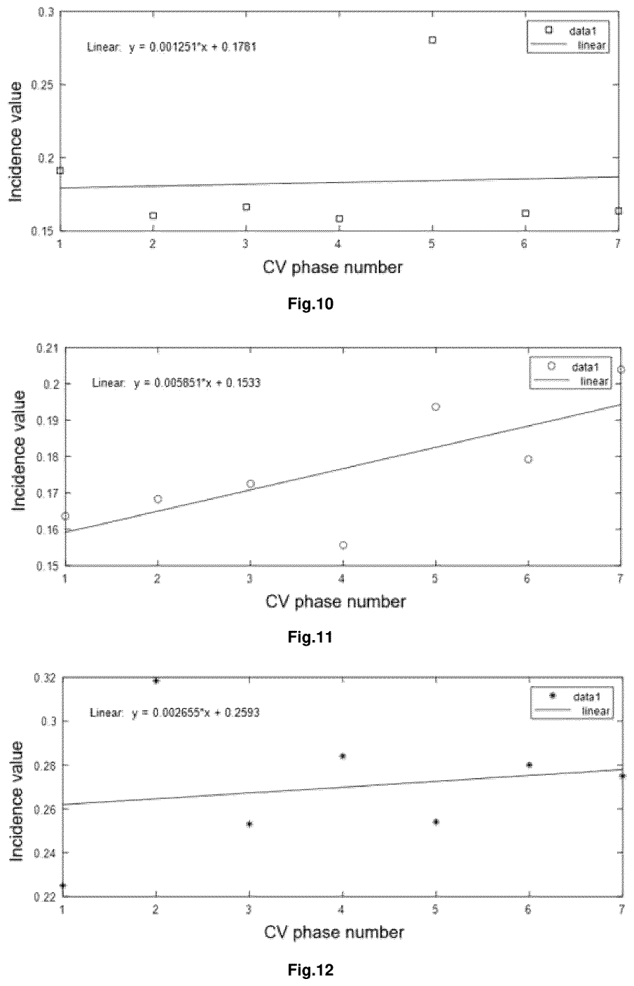

In the example illustrated in FIG. 10, the current incidence value (incidence value with the index seven) is higher than the incidence threshold, and the slope of the linear interpolation of the last seven incidence values is strictly positive (therefore, the conditions of the verifications 161 and 162 are met). Nonetheless, no alert is triggered because the current incidence value is lower than the incidence value with the index n (therefore, the condition of the verification 163 is not met).

In the examples illustrated in FIGS. 11 and 12, the current incidence value (incidence value with the index seven) is higher than the incidence threshold, the slope of the linear interpolation of the last seven incidence values is strictly positive, and the current incidence value is higher than the incidence value with the index one (therefore, all of the conditions of the verifications 161 to 163 are met and an alert is triggered. When three alerts are triggered for three consecutive CV phases, then a failure is detected.

It might be advantageous to know whether a detected failure is related to the environment in which the cell has evolved. If the failure is related to the environment, it is possible to take a corrective step at the level of the environment of the cell, and the failure will probably have a limited impact over time. A failure that is not related to the environment is probably more serious since it foreshadows a failure intrinsic to the cell, like for example a failure related to a manufacturing defect or to a precocious degradation of the cell. A failure intrinsic to the cell might require safeguarding the cell to avoid a risk of accident (swelling of the cell, risk of rupture of a case enclosing the cell, thermal runaway, fire or explosion risk, etc.).

For this purpose, and as illustrated in FIG. 1, the method 100 may include an optional step of verifying 180 whether a detected failure is related to the environment in which the cell has evolved.

In particular, this verification 180 may comprise comparing, for a given period, incidence values memorized for the cell during said period with incidence values determined and memorized for at least one other cell subjected to the same environment during said period. If the incidence values observed for one or more other cell(s) subjected to the same environment reveal a similar abnormal evolution during a given period, then it is highly probable that this abnormal behavior is related to the environment (for example because of an exceptional increase in the temperature experienced by the different cells during this period).

In one variant, the verification 180 may comprise comparing, for a given period, environment measurements performed and memorized during said period with a predetermined threshold. For example, it may consist of measurements of the temperature experienced by the cell.

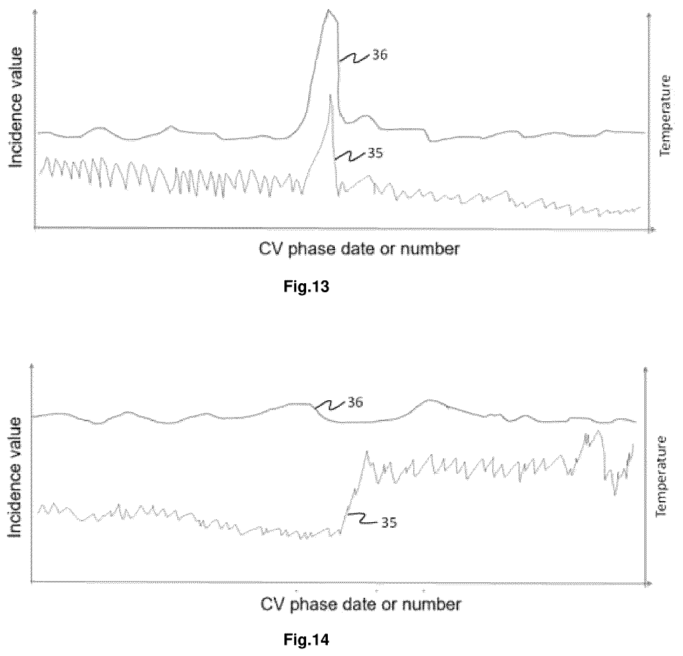

For example, FIGS. 13 and 14 illustrate the evolution over time of the incidence value of a battery cell (curve 35) as well as the evolution over time, during the same period, of the temperature experienced by the cell (curve 36).

In the example illustrated in FIG. 13, the failure evidenced by the incidence value peak is very probably related to the environment because a similar peak is observed at the same time for the temperature experienced by the cell.

However, in the example illustrated in FIG. 14, there is no particular correlation between the evolution of the incidence value and the evolution of the temperature. Hence, the failure evidenced by the abrupt increase in the incidence values does not seem to be related to the environment.

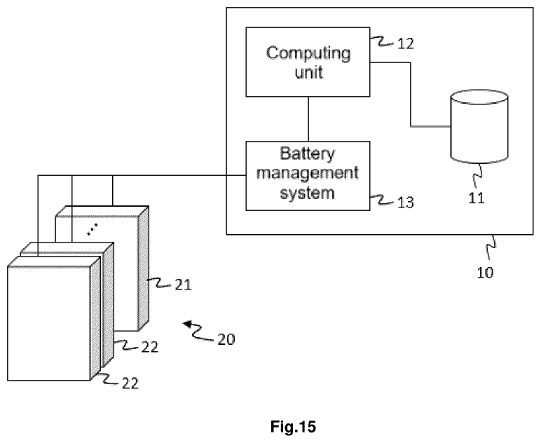

FIG. 15 schematically shows a device 10 for detecting a failure of a cell 21 of a Lithium-Ion battery 20. In particular, the device 10 includes a memory 11, a battery management system 13 and a computing unit 12 connected to the memory 11 and to the battery management system 13.

The battery management system is configured to supply current measurements performed at the level of the cell 21 during a CV phase of a CC-CV charging cycle.

The computing unit 12 is configured to implement the method 100 according to any one of the previously-described modes of implementation.

The device 10 may further include a sensor configured to measure the environment (for example a temperature sensor).

The battery management system 13 may also be configured to supply floating current measurements of one or more other cell(s) 22 subjected to the same environment as the cell 21.

The description hereinbefore clearly illustrates that, thanks to its different features and their advantages, the present invention achieves the set objectives. In particular, monitoring the total intrinsic energy or the total intrinsic spectral density of the cell allows effectively detecting a failure in advance. In tests carried out in the laboratory, it has been possible to detect several days in advance, and even several weeks in advance, the failure of a battery cell (the failure is detected in advance before swelling of the cell which generally leads to a rupture of the case of the cell).

1. A method for detecting a failure of a cell of a Lithium-Ion battery, the method including, for at least one “constant-voltage” phase, or CV phase, of a “constant-current-constant-voltage” charging cycle, or CC-CV charging cycle, of the cell:
collecting a plurality of current measurements taken at the cell during said at least one CV phase, said plurality of measurements forming a “floating current” signal,
deriving the floating current signal to obtain a floating current derivative signal,
decomposing into empirical modes the floating current derivative signal in order to obtain therefrom a representation in the form of a sum of a residual signal and of one or more intrinsic component(s),
determining an incidence value representative of a state-of-health of the cell, for said at least one CV phase, based on the intrinsic components thus obtained,
assessing a detection criterion of a failure of the cell according to the incidence value of said at least one CV phase.

2. The method according to claim 1, wherein determining the incidence value, for said at least one CV phase, comprises:
calculating an energy for each intrinsic component,
calculating a total intrinsic energy equal to a sum of the energies of the intrinsic components,
determining the incidence value according to the total intrinsic energy thus calculated.

3. The method according to claim 1, wherein determining the incidence value, for said at least one CV phase, comprises:
calculating a spectral density for each intrinsic component,
calculating a total intrinsic spectral density equal to a sum of the spectral densities of the different intrinsic components,
determining the incidence value according to the total intrinsic spectral density thus calculated.

4. The method according to claim 3, wherein, for each intrinsic component, the spectral density of the intrinsic component is calculated based on a Hilbert transform of the intrinsic component.

5. The method according to claim 1, further including, for said at least one CV phase, estimating a statistical reliability of the CV phase, according to the intrinsic components of the floating current derivative signal, and filtering the CV phase if the latter is found to be unreliable.

6. The method according to claim 5, wherein the statistical reliability of the CV phase is estimated according to an entropy calculated for a sum of the intrinsic components of the floating current derivative signal.

7. The method according to claim 5, wherein determining the incidence value, for said at least one CV phase, comprises:
calculating an energy for each intrinsic component,
calculating a total intrinsic energy equal to a sum of the energies of the intrinsic components,
determining the incidence value according to the total intrinsic energy thus calculated,
and wherein the statistical reliability of the CV phase is estimated by comparing the total intrinsic energy with a predetermined energy threshold, or with the total intrinsic energies calculated for all or part of the previous CV phases.

8. The method according to claim 1, wherein assessing the detection criterion of a failure of the cell includes comparing the incidence value with a predetermined incidence threshold, for said at least one CV phase.

9. The method according to claim 1, wherein assessing the detection criterion of a failure of the cell includes comparing a slope of a linear interpolation performed for a set of several incidence values corresponding to several consecutive CV phases with a predetermined slope threshold.

10. The method according to claim 1, wherein assessing the detection criterion of a failure of the cell includes comparing the incidence value for said at least one CV phase with an incidence value of a previous CV phase.

11. The method according to claim 1, wherein, when a failure is detected, the method further includes verifying whether the detected failure is related to the environment in which the cell has evolved.

12. The method according to claim 11, wherein verifying whether the detected failure is related to the environment comprises comparing, for a given period including said at least one CV phase, incidence values determined for the cell during said period with incidence values determined for at least one other cell subjected to the same environment during said period.

13. The method according to claim 11, wherein verifying whether the detected failure is related to the environment comprises comparing, for a given period including said at least one CV phase, environment measurements performed during said period with a predetermined threshold.

14. A device for detecting a failure of a cell of a Lithium-Ion battery, said device including:
a battery management system configured to supply current measurements taken at the cell during a “constant-voltage” phase, or CV phase, of a “constant-current-constant-voltage” charging cycle, or CC-CV charging cycle, of the cell,
a computing unit connected to the battery management system, said computing unit being configured to implement a method according to claim 1.
